(19) United States
(12) Patent Application Publication
(10) Pub. No.: US 2026/0045703 A1
(43) Pub. Date: Feb. 12, 2026

(54) ELECTRONIC DEVICE WITH A RECEIVER INCLUDING RYDBERG SENSORS

(71) Applicant: T-Mobile USA, Inc., Bellevue, WA (US)

(72) Inventor: Chad Au, Kirkland, WA (US)

(21) Appl. No.: 18/798,610

(22) Filed: Aug. 8, 2024

(51) Int. Cl. H01Q 21/06; G01R 29/12; H04B 7/0413

(52) U.S. Cl. CPC H01Q 21/06; G01R 29/12; H04B 7/0413

(57) ABSTRACT

Electronic devices include a transmitter portion that includes one or more antennas and a receiver portion that includes one or more Rydberg sensors. The Rydberg sensors are configured to receive radio frequency (RF) signals. The Rydberg sensors are a much more sensitive mechanism for the detection of miniscule electromagnetic fields in comparison to typical antennas. The transmitter portion transmits RF signals via the one or more antennas.

### BACKGROUND

Services provided by wireless communication networks are continually growing in popularity. A common experience of users of wireless communication networks includes having poor coverage due to attenuation of a radio frequency (RF) signal when the RF signals are propagating through materials into a building. Often, what began as a robust RF signal outdoors may often degrade into a weak signal once indoors. This may also be the situation if the user is at the very edge of wireless communication network coverage, where the RF signal from the closest cell site has become weak over distance. Additionally, traditional antennas and accompanying duplexers for receiving RF signals via transceivers often interfere with received electromagnetic fields.

### BRIEF DESCRIPTION OF THE DRAWINGS

The detailed description is described with reference to the accompanying figures. In the figures, the left-most digit(s) of a reference number identifies the figure in which the reference number first appears. The use of the same reference numbers in different figures indicates similar or identical components or features.

FIGS. 1A and 1B schematically illustrate example block diagrams of an architecture for a portion of a wireless communication network and an electronic device including Rydberg sensors for receiving RF signals from the wireless communication network, according to some implementations.

FIG. 2 is a flow diagram illustrating an example process associated with electronic devices including Rydberg sensors for receiving RF signals from the wireless communication network, according to some implementations.

FIG. 3 schematically illustrates a component level view of an example electronic device configured for use with the techniques and architecture described herein, according to some implementations.

### DETAILED DESCRIPTION

Described herein are electronic devices for use within wireless communication networks, where the electronic device includes Rydberg sensors for receiving radio frequency (RF) signals from the wireless communication networks. Wireless communication networks provide many services to users of electronic devices, e.g., smart phones, televisions, smart appliances, tablets, personal computers, etc. As previously noted, common experience of users of wireless communication networks includes having poor coverage due to attenuation of a radio frequency (RF) signal when the RF signals are propagating through materials into a building. Often, what began as a robust RF signal outdoors may often degrade into a weak signal once indoors. This may also be the situation if the user is at the very edge of wireless communication network coverage, where the RF signal from the closest cell site has become weak over distance. Additionally, traditional antennas and accompanying duplexers for receiving RF signals via transceivers often interfere with received electromagnetic fields.

In configurations, electronic devices include a transmitter portion that includes one or more antennas and a receiver portion that includes one or more Rydberg sensors. The Rydberg sensors are configured to receive radio frequency (RF) signals. The Rydberg sensors are a much more sensitive mechanism for the detection of miniscule electromagnetic fields in comparison to typical antennas. The transmitter portion transmits RF signals via the one or more antennas.

By incorporating Rydberg sensors into the receiver portions of the electronic device, the receiver performance may potentially be improved by taking advantage of a much more sensitive mechanism for the detection of miniscule electromagnetic (EM) fields. Since the output of the Rydberg sensor is demodulated data, base band processing may potentially be eliminated.

Briefly, Rydberg sensors operate using what is commonly referred to as Rydberg atoms. Rydberg atoms are atoms with one or more electrons excited to a very high principal quantum number n. These Rydberg atoms have large dipole moments (scale as n²), which make them very useful for electric (E) field sensors. The use of Rydberg states of an alkali atomic vapor placed in glass cells for radio frequency (RF) E-field strength and power sensors has made great strides in recent years. Electromagnetically induced transparency (EIT) is used in this approach for E-field sensing, performed when an RF field is either on-resonance of a Rydberg transition (using Autler-Townes (AT) splitting) or off-resonance (using ac Stark shifts).

In order to detect and receive carrier phase-modulated signals (the basis of most digital modulation schemes, e.g., binary phase-shift keying (BPSK), quadrature phase-shift keying (QPSK), and quadrature amplitude modulation (QAM)), detection of the phase of the carrier RF signal is required. This EIT scheme has been very successful in detecting the amplitude of continuous-wave (CW) carriers.

A widely used modulation scheme for digital communications is phase-shift keying (PSK) using both BPSK and QPSK. In these modulation schemes, data is transmitted by changing (or modulating) the phase of the CW carrier. BPSK uses two different phase states to transmit data, in which the carrier frequency phase is changed between 0° and 180°. Each phase state represents one transmitted symbol, and each symbol is mapped into bits “1” or “0.” QPSK is a type of PSK, where each transmitted symbol (or phase state) is mapped into two bits. This is done by choosing one of four possible phases applied to a CW carrier (e.g., 45° (binary state “00”), 135° (binary state “01”), −45° (binary state “10”), and −135° (binary state “11”)). Using both the phase and the amplitude, this idea is extended to QAM, where 16QAM corresponds to 16 phase and amplitude states; each phase state is a transmitted symbol (each symbol corresponds to 4 bits, “0000,” “1000,” “1100,” etc.). Continuing this, (2ⁿ)QAM corresponds to 2ⁿ phase and amplitude states; each phase state is a transmitted symbol (each symbol corresponds to n bits). Thus, to receive BPSK, QPSK, and QAM signals, one needs to measure and detect the phase and amplitude of the CW carrier. The Rydberg atom-based mixer allows for measuring the phase and amplitude of a carrier, and this approach may be used to receive BPSK, QPSK, 16QAM, 32QAM, and 64QAM modulated signals.

For the atom-based mixer, a reference RF field on-resonance with the Rydberg atom transition acts as a local oscillator (LO). The “LO” field causes the EIT/AT effect in the Rydberg atoms, which is used to down-convert a second co-polarized RF field. This second field is detuned from the “LO” field and is the digital modulated carrier. The frequency difference between the LO and the SIG is an intermediate frequency (IF), and the IF is detected by optically probing the Rydberg atoms. The phase of the IF signal corresponds directly to the relative phase between the “LO” and “SIG” signals. In effect, the atom-based mixer does all the down-conversion of the “SIG” and the “LO,” and a direct read-out of the phase of SIG is obtained by the probe laser propagating through the atomic vapor. By measuring the relative phase shift of the IF signal (via a photodetector), the phase states of BPSK, QPSK, and QAM signals may be determined.

The EIT/AT technique involves monitoring the transmission of the “probe” laser through the vapor cell. The second laser (“coupling” laser) establishes a coherence in the atomic states and enhances the probe transmission through the atoms. An applied RF field (the LO field in this example) alters the susceptibility of the atomic vapor, which results in a change in the probe laser transmission. The presence of both LO and SIG fields creates a beat note, and the beat note results in AM of the probe transmission, where the amplitude of the probe transmission varies as cos(2πf_{IF}t+Δφ) (where f_{IF} is the frequency of the IF field and Δφ is the phase difference between the LO and SIG fields). This AM of the probe laser transmission may be detected with the photodetector and used to determine the phase of the SIG signal. For a pure AM or FM carrier, the Rydberg atoms automatically demodulate the carrier, and output of the photodetector gives a direct read-out of the baseband signal (the information being transmitted). For a phase-modulated carrier, the Rydberg atoms automatically down-convert the carrier to the IF, which contains the phase states of the different phase-modulation schemes.

Accordingly, in configurations, an electronic device includes multiple integrated antennas for one or more transmitter portions or paths of the electronic device. The electronic device also includes Rydberg sensors for one or more receiver portions or paths. In configurations, there may be five antennas for the one or more transmit portions and five Rydberg sensors for the one or more receiver portions. As an example, the electronic device includes a microcontroller and a keypad coupled to the microcontroller. A display component is also included that may display a visual signal based upon receipt of RF signals via the Rydberg sensors. The keypad may be used as a user input for the electronic device. An audio component may also be provided for emitting an audio signal via, for example, one or more speakers of the electronic device based upon received RF signals via the one or more Rydberg sensors.

In configurations, the Rydberg sensors may be coupled to a detector that detects the demodulated data output by the Rydberg sensors and provides them to the microcontroller, the display component, and/or the audio component. In configurations, the detector may provide the demodulated data to the microcontroller for processing, which then provides the demodulated data to the display component and/or the audio component.

The transmitter portion includes a digital signal processing (DSP) core for processing RF signals to be provided to a transmitter. The transmitter then provides the RF signals to one or more of the antennas for broadcasting of the RF signals.

While it is described that five Rydberg sensors and five antennas are positioned within the electronic device, there may be more or fewer Rydberg sensors and/or antennas depending upon the configuration of the electronic device. Additionally, there need not be the same number of Rydberg sensors as there are antennas. In configurations, the number of Rydberg sensors included in the receiver portion and the number of antennas included in the transmitter portion are defined by a multi-input multiple-output (MIMO) antenna scheme of the electronic device. More particularly, based at least in part on the MIMO antenna scheme, the number of Rydberg sensors and the number of antennas is defined by a number of frequency bands and the width of the frequency bands to be supported by the electronic device.

Accordingly, as an example, an electronic device, configured for communication over a wireless communication network, comprises a transmitter portion comprising one or more antennas; and a receiver portion comprising one or more Rydberg sensors configured to receive radio frequency (RF) signals.

In configurations, the receiver portion comprises multiple Rydberg sensors.

In some configurations, the transmitter portion comprises multiple antennas.

In configurations, the receiver portion comprises five Rydberg sensors.

In some configurations, the transmitter portion comprises five antennas.

In configurations, a first number of Rydberg sensors included in the receiver portion and a second number of antennas included in the transmitter portion are defined by a multiple-input multiple-output (MIMO) antenna scheme.

In some configurations, based at least in part on the MIMO antenna scheme, the first number of Rydberg sensors and the second number of antennas are defined by a number of frequency bands and a width of the frequency bands to be supported by the portable electronic device.

In configurations, the one or more Rydberg sensors each comprise a probe laser and a coupling laser, and wherein a first wavelength of the probe laser and a second wavelength of the coupling laser are selected to correspond to RF operating frequencies of the wireless communication network.

In configurations, the electronic device comprises one of a smart phone, a television, a smart appliance, tablets, or a personal computer.

As another example, a method, within a wireless communication network, comprises receiving, at one or more Rydberg sensors of a receiver portion of an electronic device, first radio frequency (RF) signals; and based at least in part on receiving the first RF signals, at least one of (i) emitting an audio signal via an audio component of the electronic device or (ii) displaying a visual signal via a display component of the electronic device. In some configurations, the method also comprises transmitting, via one or more antennas of a transmitter portion of the electronic device, second RF signals.

Thus, by incorporating Rydberg sensors into the receiver portions of the electronic devices, the receiver performance may potentially be improved by taking advantage of a much more sensitive mechanism for the detection of miniscule electromagnetic fields. Since the output of the Rydberg sensor is demodulated data, base band processing may potentially be eliminated. In addition to utilizing a more efficient electromagnetic field sensing device instead of a passive antenna in the receiver portion of the electronic devices, duplexers/filters may be removed for dedicated transmitter and receiver paths in a modem, which lends the radio to a cleaner RF system, e.g., lower noise in receiving the downlink (DL). Also, use of Rydberg sensors may keep disturbance of the desired RF signal to a minimum, allowing the detection of even lower power density EM fields.

Certain implementations and embodiments of the disclosure will now be described more fully below with reference to the accompanying figures, in which various aspects are shown. However, the various aspects may be implemented in many different forms and should not be construed as limited to the implementations set forth herein. The disclosure encompasses variations of the embodiments, as described herein. Like numbers refer to like elements throughout.

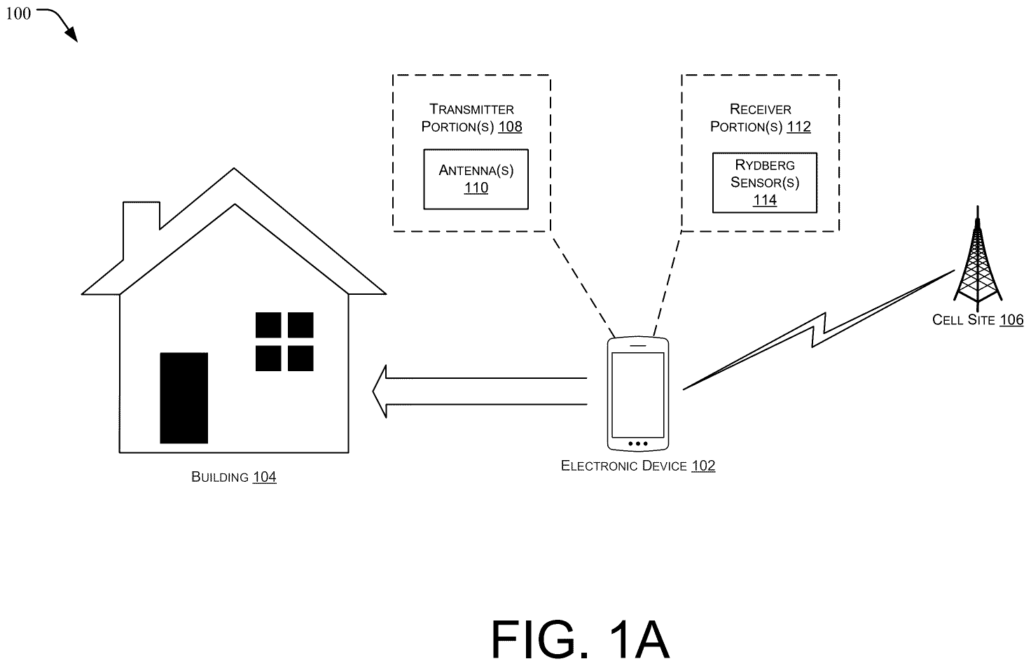

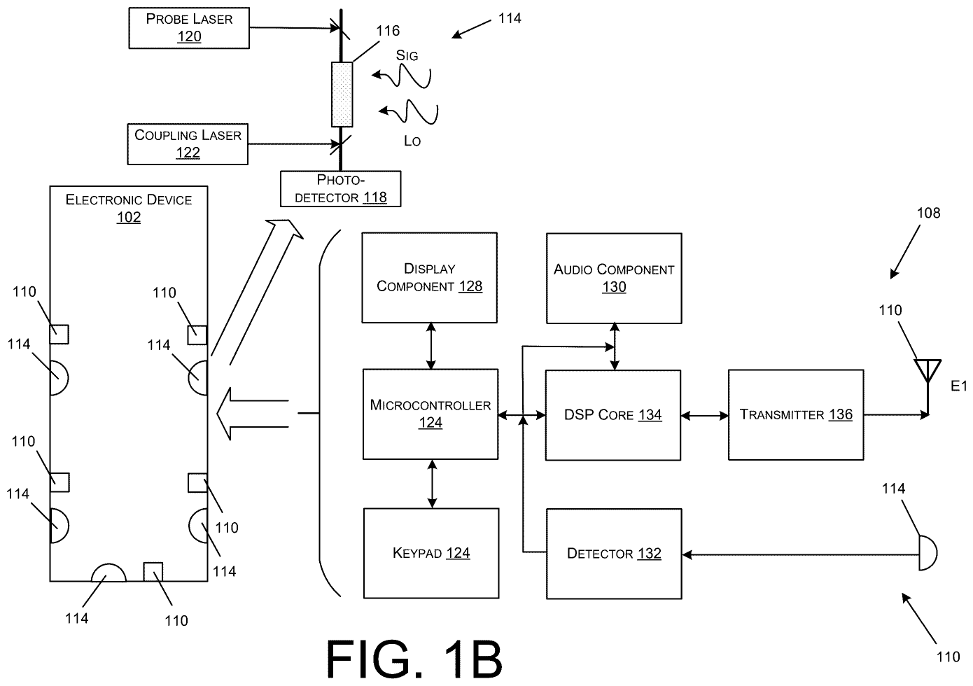

FIG. 1A schematically illustrates an example portion of a wireless communication network 100. An electronic device 102, e.g., a smart phone, a television, a smart appliance, a tablet, a personal computer, etc., is configured to operate within the wireless communication network 100.

As previously noted, common experience of users of wireless communication networks includes having poor coverage due to attenuation of a radio frequency (RF) signal when the RF signals are propagating through materials into a building 104. Often, what began as a robust RF signal outdoors may often degrade into a weak signal once indoors. This may also be the situation if the user is at the very edge of wireless communication network coverage, where the RF signal from the closest cell site 106 has become weak over distance.

In configurations, the electronic device 102 includes one or more transmitter portion(s) 108 that includes one or more antenna(s) 110 and one or more receiver portion(s) 112 that includes one or more Rydberg sensor(s) 114. The Rydberg sensors 114 are configured to receive radio frequency (RF) signals from the cell site 106. The Rydberg sensors 114 are a much more sensitive mechanism for the detection of miniscule electromagnetic (EM) fields in comparison to typical antennas, e.g., antennas 110. The transmitter portion 108 transmits RF signals via one or more antennas 110.

FIG. 1B schematically illustrates an example electronic device 102. In configurations, the electronic device 102 includes multiple integrated antennas 110 for one or more transmitter portions or paths 108 of the electronic device 102 for transmitting RF signals. The electronic device 102 also includes Rydberg sensors 114 for one or more receiver portions or paths 112 for receiving RF signals.

Briefly, Rydberg sensors 114 operate using what is commonly referred to as Rydberg atoms in a vapor cell 116. Rydberg atoms are atoms with one or more electrons excited to a very high principal quantum number n. These Rydberg atoms have large dipole moments (scale as n²), which make them very useful for electric (E) field sensors. The use of Rydberg states of an alkali atomic vapor placed in glass cells for radio frequency (RF) E-field strength and power sensors has made great strides in recent years. Electromagnetically induced transparency (EIT) is used in this approach for E-field sensing, performed when an RF field is either on-resonance of a Rydberg transition (using Autler-Townes (AT) splitting) or off-resonance (using ac Stark shifts).

In order to detect and receive carrier phase-modulated signals (the basis of most digital modulation schemes, e.g., binary phase-shift keying (BPSK), quadrature phase-shift keying (QPSK), and quadrature amplitude modulation (QAM)), detection of the phase of the carrier RF signal is required. This EIT scheme has been very successful in detecting the amplitude of continuous-wave (CW) carriers.

A widely used modulation scheme for digital communications is phase-shift keying (PSK) using both BPSK and QPSK. In these modulation schemes, data is transmitted by changing (or modulating) the phase of the CW carrier. BPSK uses two different phase states to transmit data, in which the carrier frequency phase is changed between 0° and 180°. Each phase state represents one transmitted symbol, and each symbol is mapped into bits “1” or “0.” QPSK is a type of PSK, where each transmitted symbol (or phase state) is mapped into two bits. This is done by choosing one of four possible phases applied to a CW carrier (e.g., 45° (binary state “00”), 135° (binary state “01”), −45° (binary state “10”), and −135° (binary state “11”)). Using both the phase and the amplitude, this idea is extended to QAM, where 16QAM corresponds to 16 phase and amplitude states; each phase state is a transmitted symbol (each symbol corresponds to 4 bits, “0000,” “1000,” “1100,” etc.). Continuing this, (2ⁿ)QAM corresponds to 2ⁿ phase and amplitude states; each phase state is a transmitted symbol (each symbol corresponds to n bits). Thus, to receive BPSK, QPSK, and QAM signals, one needs to measure and detect the phase and amplitude of the CW carrier. The Rydberg atom-based mixer allows for measuring the phase and amplitude of a carrier, and this approach may be used to receive BPSK, QPSK, 16QAM, 32QAM, and 64QAM modulated signals.

For the atom-based mixer, a RF field (LO) on-resonance with the Rydberg atom transition acts as a local oscillator (LO). The “LO” field causes the EIT/AT effect in the Rydberg atoms in the vapor cell, which is used to down-convert a second co-polarized RF field. This second field is detuned from the “LO” field and is the digital modulated carrier (SIG). The frequency difference between the LO and the SIG is an intermediate frequency (IF), and the IF is detected by optically probing the Rydberg atoms in the vapor cell 116. The phase of the IF signal corresponds directly to the relative phase between the “LO” and “SIG” signals. In effect, the atom-based mixer does all the down-conversion of the “SIG” and the “LO,” and a direct read-out of the phase of SIG is obtained by a probe laser 120 propagating through the atomic vapor in the vapor cell 116. By measuring the relative phase shift of the IF signal via a photodetector 118, the phase states of BPSK, QPSK, and QAM signals may be determined.

The EIT/AT technique involves monitoring the transmission of the probe laser 120 through the vapor cell 116. A second laser, coupling laser 122, establishes a coherence in the atomic states and enhances the probe transmission through the atoms. An applied RF field (the LO field in this example) alters the susceptibility of the atomic vapor in the vapor cell, which results in a change in the probe laser transmission. The presence of both LO and SIG fields creates a beat note, and the beat note results in AM of the probe transmission, where the amplitude of the probe transmission varies as cos(2πf_{IF}t+Δφ) (where f_{IF} is the frequency of the IF field and Δφ is the phase difference between the LO and SIG fields). This AM of the probe laser transmission may be detected with the photodetector 118 and used to determine the phase of the SIG signal. For a pure AM or FM carrier, the Rydberg atoms automatically demodulate the carrier, and output of the photodetector 118 gives a direct read-out of the baseband signal (the information being transmitted). For a phase-modulated carrier, the Rydberg atoms automatically down-convert the carrier to the IF, which contains the phase states of the different phase-modulation schemes.

As may be seen in FIG. 1B, in configurations, there may be five antennas 110 for the one or more transmitter portions 108 and five Rydberg sensors 114 for the one or more receiver portions 112. As an example, the electronic device 102 includes a microcontroller 124 and a keypad 126 coupled to the microcontroller 124. A display component 128 is also included that may display a visual signal via, for example, a display screen, based upon receipt of RF signals via the Rydberg sensors 114. The keypad 126 may be used as a user input for the electronic device 102. An audio component 130 may also be provided for emitting an audio signal via, for example, one or more speakers of the electronic device 102 based upon received RF signals via the one or more Rydberg sensors 114.

In configurations, the Rydberg sensors 114 may be coupled to a detector 132 that detects the demodulated data output by the Rydberg sensors 114 and provides them to the microcontroller 124, the display component 128, and/or the audio component 130. In configurations, the detector 132 may provide the demodulated data to the microcontroller 124 for processing, which then provides the demodulated data to the display component 128 and/or the audio component 130.

The transmitter portion 108 includes a digital signal processing (DSP) core 134 for processing RF signals to be provided to a transmitter 136 of the transmitter portion 108. The transmitter 136 then provides the RF signals to one or more of the antennas 110 for broadcasting of the RF signals.

In the example of FIG. 1B, five Rydberg sensors 114 and five antennas 110 are displayed positioned around a periphery of the electronic device 102, there may be more or fewer Rydberg sensors 114 and/or antennas 110 depending upon the configuration of the electronic device 102. Additionally, there need not be the same number of Rydberg sensors 114 as there are antennas 110. In configurations, the number of Rydberg sensors 114 included in the receiver portion 112 and the number of antennas 110 included in the transmitter portion 108 are defined by a multi-input multiple-output (MIMO) antenna scheme of the electronic device 102. More particularly, based at least in part on the MIMO antenna scheme, the number of Rydberg sensors 114 and the number of antennas 110 is defined by a number of frequency bands and the width of the frequency bands to be supported by the electronic device 102.

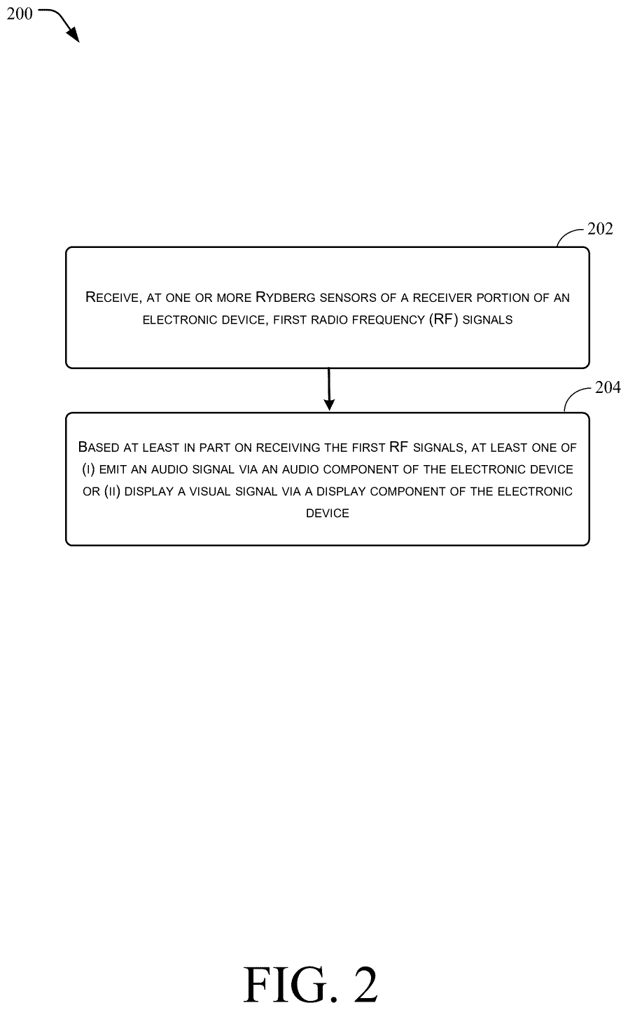

FIG. 2 is a flow diagram illustrating an example process associated with electronic devices including Rydberg sensors for receiving RF signals from a wireless communication network, as discussed herein. The processes are illustrated as a collection of blocks in a logical flow diagram, which represent a sequence of operations, some or all of which can be implemented in hardware, software, or a combination thereof. In the context of software, the blocks represent computer-executable instructions stored on one or more computer-readable media that, when executed by one or more processor(s), performs the recited operations. Generally, computer-executable instructions include routines, programs, objects, components, encryption, deciphering, compressing, recording, data structures and the like that perform particular functions or implement particular abstract data types.

The order in which the operations are described should not be construed as a limitation. Any number of the described blocks can be combined in any order and/or in parallel to implement the processes, or alternative processes, and not all of the blocks need be executed. For discussion purposes, the processes herein are described with reference to the frameworks, architectures and environments described in the examples herein, although the processes may be implemented in a wide variety of other frameworks, architectures or environments.

FIG. 2 is a flow diagram illustrating an example process 200 associated with the electronic devices including Rydberg sensors for receiving RF signals from a wireless communication network, according to some implementations.

At 202, one or more Rydberg sensors of a receiver portion of an electronic device receive first radio frequency (RF) signals. For example, in configurations, the electronic device 102 includes a transmitter portion 108 that includes one or more antenna(s) 110 and a receiver portion 112 that includes one or more Rydberg sensor(s) 114. The Rydberg sensors 114 are configured to receive radio frequency (RF) signals from the cell site 106. The Rydberg sensors 114 are a much more sensitive mechanism for the detection of miniscule electromagnetic (EM) fields in comparison to typical antennas, e.g., antennas 110. The transmitter portion 108 transmits RF signals via one or more antennas 110. FIG. 1B schematically illustrates an example electronic device 102. In configurations, the electronic device 102 includes multiple integrated antennas 110 for one or more transmitter portions or paths 108 of the electronic device 102 for transmitting RF signals. The electronic device 102 also includes Rydberg sensors 114 for one or more receiver portions or paths 112 for receiving RF signals.

At 204, based at least in part on receiving the first RF signals, at least one of (i) an audio signal is emitted via an audio component of the electronic device or (ii) a visual signal is displayed via a display component of the electronic device. For example, as may be seen in FIG. 1B, in configurations, there may be five antennas 110 for the one or more transmitter portions 108 and five Rydberg sensors 114 for the one or more receiver portions 112. As an example, the electronic device 102 includes a microcontroller 124 and a keypad 126 coupled to the microcontroller 124. A display component 128 is also included that may display a visual signal via, for example, a display screen, based upon receipt of RF signals via the Rydberg sensors 114. The keypad 126 may be used as a user input for the electronic device 102. An audio component 130 may also be provided for emitting an audio signal via, for example, one or more speakers of the electronic device 102 based upon received RF signals via the one or more Rydberg sensors 114.

In configurations, the Rydberg sensors 114 may be coupled to a detector 132 that detects the demodulated data output by the Rydberg sensors 114 and provides them to the microcontroller 124, the display component 128, and/or the audio component 130. In configurations, the detector 132 may provide the demodulated data to the microcontroller 124 for processing, which then provides the demodulated data to the display component 128 and/or the audio component 130.

Thus, by incorporating Rydberg sensors 114 into the receiver portions 112 of the electronic devices 102, the receiver performance may potentially be improved by taking advantage of a much more sensitive mechanism for the detection of miniscule electromagnetic fields. Since the output of the Rydberg sensor 114 is demodulated data, base band processing may potentially be eliminated. In addition to utilizing a more efficient electromagnetic field sensing device instead of a passive antenna in the receiver portion 112 of the electronic devices 102, duplexers/filters may be removed for dedicated transmitter and receiver paths in a modem, which lends the radio to a cleaner RF system, e.g., lower noise in receiving the downlink (DL). Also, use of Rydberg sensors 114 may keep disturbance of the desired RF signal to a minimum, allowing the detection of even lower power density EM fields.

Electronic devices 102 may be implemented as any suitable mobile computing device configured to communicate over a wireless and/or wireline network, including, without limitation, a mobile phone (e.g., a smart phone), a tablet computer, a laptop computer, a portable digital assistant (PDA), a wearable computer (e.g., electronic/smart glasses, a smart watch, fitness trackers, etc.), a networked digital camera, and/or similar mobile devices. Although this description predominantly describes the electronic devices 102 as being “mobile” (i.e., configured to be carried and moved around), it is to be appreciated that the electronic devices 102 may represent various types of communication devices that are generally stationary as well, such as televisions, desktop computers, game consoles, set top boxes, Internet of Things (IoT) devices, and the like. In this sense, the terms “communication device,” “wireless device,” “wireline device,” “mobile device,” “computing device,” “portable electronic device,” and “user equipment (UE)” may be used interchangeably herein to describe any communication device capable of performing the techniques described herein. Furthermore, the portable electronic devices 102 may be capable of communicating over wired networks, and/or wirelessly using any suitable wireless communications/data technology, protocol, or standard, such as Global System for Mobile Communications (GSM), Time Division Multiple Access (TDMA), Universal Mobile Telecommunications System (UMTS), Evolution-Data Optimized (EVDO), Long Term Evolution (LTE), Advanced LTE (LTE+), Generic Access Network (GAN), Unlicensed Mobile Access (UMA), Code Division Multiple Access (CDMA), Orthogonal Frequency Division Multiple Access (OFDM), General Packet Radio Service (GPRS), Enhanced Data GSM Environment (EDGE), Advanced Mobile Phone System (AMPS), High Speed Packet Access (HSPA), evolved HSPA (HSPA+), Voice over IP (VoIP), Voice over LTE (VoLTE), 5G, IEEE 802.1x protocols, WiMAX, Wi-Fi, and/or any future IP-based network technology or evolution of an existing IP-based network technology.

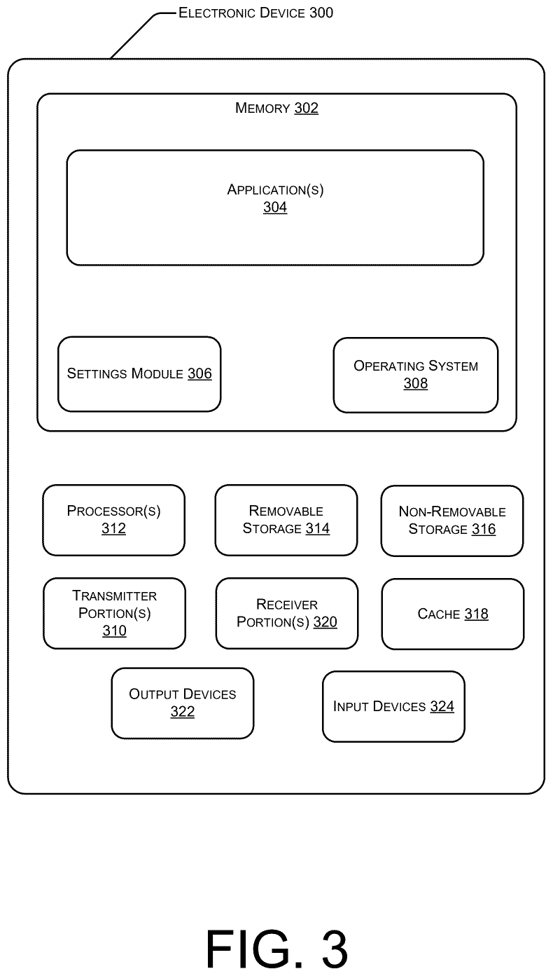

FIG. 3 schematically illustrates a component level view of a mobile device 300, such as electronic devices 102, configured to function within wireless communication networks. As illustrated, the mobile device 300 comprises a system memory 302, e.g., computer-readable media, storing application(s) 304. Alternatively, the functions and UIs may be implemented, wholly or in part, via firmware (not illustrated). The mobile device also comprises a settings module 306, and an operating system 308. Also, the mobile device 300 includes processor(s) 312, a removable storage 314, a non-removable storage 316, cache 318, one or more transmitter portions 310 (e.g., transmitter portion(s) 108), one or more receiver portions 320 (e.g., receiver portion(s) 112), output device(s) 322, and input device(s) 324. In various implementations, system memory 302 is volatile (such as RAM), non-volatile (such as ROM, flash memory, etc.) or some combination of the two. In some implementations, the processor(s) 312 is a central processing unit (CPU), a graphics processing unit (GPU), or both CPU and GPU, or any other sort of processing unit.

The mobile device 300 may also include additional data storage devices (removable and/or non-removable) such as, for example, magnetic disks, optical disks, or tape. Such additional data storage may include removable storage 314 and non-removable storage 316. Additionally, the mobile device 300 includes cache 318.

Non-transitory computer-readable media may include volatile and nonvolatile, removable and non-removable tangible, physical media implemented in technology for storage of information, such as computer readable instructions, data structures, program modules, or other data. System memory 302, removable storage 314, non-removable storage 316 and cache 318 are all examples of non-transitory computer-readable media. Non-transitory computer-readable media include, but are not limited to, RAM, ROM, EEPROM, flash memory or other memory technology, CD-ROM, digital versatile discs (DVD) or other optical storage, magnetic cassettes, magnetic tape, magnetic disk storage or other magnetic storage devices, or any other tangible, physical medium which can be used to store the desired information and which can be accessed by the mobile device 300. Any such non-transitory computer-readable media may be part of the mobile device 300. The processor(s) 312 may be configured to execute instructions, which may be stored in the non-transitory computer-readable media or in other computer-readable media accessible to the processor(s) 312.

In some implementations, the transmitter portion(s) 310 include any sort of transmitters known in the art. For example, the transmitter portion(s) 310 may include a radio transmitter that performs the function of transmitting radio frequency communications via one or more antennas (e.g., antenna(s) 110). Also, or alternatively, the transmitter portion(s) 310 may include wireless modem(s) to facilitate wireless connectivity with other computing devices. Further, the transmitter portion(s) 310 may include wired communication components, such as an Ethernet port, for communicating with other networked devices.

In some implementations, the receiver portion(s) 320 include any sort of receivers known in the art but include Rydberg sensors (e.g., Rydberg sensor(s) 114). For example, the receiver portion(s) 320 may include a radio receiver that performs the function of receiving radio frequency communications via one or more Rydberg sensors (e.g., Rydberg sensor(s) 114). Also, or alternatively, the receiver portion(s) 320 may include wireless modem(s) to facilitate wireless connectivity with other computing devices. Further, the receiver portion(s) 320 may include wired communication components, such as an Ethernet port, for communicating with other networked devices.

In some implementations, the output devices 322 include any sort of output devices known in the art, such as a display (e.g., a liquid crystal display), speakers, a vibrating mechanism, or a tactile feedback mechanism. Output devices 322 also include ports for one or more peripheral devices, such as headphones, peripheral speakers, or a peripheral display.

In various implementations, input devices 324 include any sort of input devices known in the art. For example, input devices 324 may include a camera, a microphone, a keyboard/keypad, or a touch-sensitive display. A keyboard/keypad may be a push button numeric dialing pad (such as on a typical telecommunication device), a multi-key keyboard (such as a conventional QWERTY keyboard), or one or more other types of keys or buttons, and may also include a joystick-like controller and/or designated navigation buttons, or the like. The input devices 324 may be used to enter preferences of a user of the mobile device 300 to define how the user wishes certain calls from third parties to be handled by the wireless communication network, as previously described herein.

While the example clauses described above are described with respect to one particular example implementation, it should be understood that, in the context of this document, the content of the example clauses can also be implemented via a method, device, system, a computer-readable medium, and/or another implementation. Additionally, any of examples may be implemented alone or in combination with any other one or more of the other examples.

What is claimed is:

1. An electronic device configured for communication over a wireless communication network, the electronic device comprising:
a transmitter portion comprising one or more antennas; and
a receiver portion comprising one or more Rydberg sensors configured to receive radio frequency (RF) signals.

2. The electronic device of claim 1, wherein the receiver portion comprises multiple Rydberg sensors.

3. The electronic device of claim 2, wherein the transmitter portion comprises multiple antennas.

4. The electronic device of claim 3, wherein the receiver portion comprises five Rydberg sensors.

5. The electronic device of claim 4, wherein the transmitter portion comprises five antennas.

6. The electronic device of claim 3, wherein a first number of Rydberg sensors included in the receiver portion and a second number of antennas included in the transmitter portion are defined by a multiple-input multiple-output (MIMO) antenna scheme.

7. The electronic device of claim 6, wherein based at least in part on the MIMO antenna scheme, the first number of Rydberg sensors and the second number of antennas are defined by a number of frequency bands and a width of the frequency bands to be supported by the electronic device.

8. The electronic device of claim 1, wherein the one or more Rydberg sensors each comprise a probe laser and a coupling laser, and wherein a first wavelength of the probe laser and a second wavelength of the coupling laser are selected to correspond to RF operating frequencies of the wireless communication network.

9. The electronic device of claim 1, wherein the electronic device comprises one of a smart phone, a television, a smart appliance, tablets, or a personal computer.

10. A method within a wireless communication network, the method comprising:
receiving, at one or more Rydberg sensors of a receiver portion of an electronic device, first radio frequency (RF) signals; and
based at least in part on receiving the first RF signals, at least one of (i) emitting an audio signal via an audio component of the electronic device or (ii) displaying a visual signal via a display component of the electronic device.

11. The method of claim 10, wherein the receiver portion comprises multiple Rydberg sensors.

12. The method of claim 11, further comprising:
transmitting, via one or more antennas of a transmitter portion of the electronic device, second RF signals.

13. The method of claim 12, wherein the receiver portion comprises five Rydberg sensors.

14. The method of claim 13, wherein the transmitter portion comprises five antennas.

15. The method of claim 12, wherein a first number of Rydberg sensors included in the receiver portion and a second number of antennas included in the transmitter portion are defined by a multiple-input multiple-output (MIMO) antenna scheme.

16. The method of claim 15, wherein based at least in part on the MIMO antenna scheme, the first number of Rydberg sensors and the second number of antennas are defined by a number of frequency bands and a width of the frequency bands to be supported by the electronic device.

17. The method of claim 10, wherein the one or more Rydberg sensors each comprise a probe laser and a coupling laser, and wherein a first wavelength of the probe laser and a second wavelength of the coupling laser are selected to correspond to RF operating frequencies of the wireless communication network.

18. The method of claim 10, wherein the electronic device comprises one of a smart phone, a television, a smart appliance, tablets, or a personal computer.

19. An electronic device configured for communication over a wireless communication network, the electronic device comprising:
a transmitter portion comprising one or more antennas; and
a receiver portion comprising one or more Rydberg sensors configured to receive radio frequency (RF) signals,
wherein a first number of Rydberg sensors included in the receiver portion and a second number of antennas included in the transmitter portion are defined by a multiple-input multiple-output (MIMO) antenna scheme.

20. The electronic device of claim 19, wherein based at least in part on the MIMO antenna scheme, the first number of Rydberg sensors and the second number of antennas are defined by a number of frequency bands and a width of the frequency bands to be supported by the electronic device.
